(19) United States
(12) Patent Application Publication
(10) Pub. No.: US 2011/0294279 A1
(43) Pub. Date: Dec. 1, 2011

(54) WORKING METHOD FOR SAPPHIRE SUBSTRATE

(75) Inventor: Takashi Okamura, Ota-ku (JP)

(73) Assignee: DISCO CORPORATION, Tokyo (JP)

(21) Appl. No.: 13/117,222

(22) Filed: May 27, 2011

(30) Foreign Application Priority Data
Jun. 1, 2010 (JP) 2010-126102

(51) Int. Cl. H01L 21/78

(52) U.S. Cl. 438/460; 257/E21.599

(57) ABSTRACT

A working method for a sapphire substrate for dividing a sapphire substrate along a set planned dividing line includes a cutting groove forming step of positioning a cutting blade, which includes a cutting edge to which diamond grain is secured by nickel plating, to a planned dividing line of the sapphire substrate and feeding the cutting blade and the sapphire substrate relative to each other for working while rotating the cutting blade to form a cutting groove, which serves as a start point of break, along the planned division line on the sapphire substrate, and a breaking step of applying external force to the sapphire substrate, for which the cutting groove forming step is carried out, to break the sapphire substrate along the planned dividing line along which the cutting groove is formed. The cutting groove forming step is set such that a rotational speed of the cutting blade is 20000 to 35000 rpm, a cutting-in depth of the cutting blade is 5 to 15 μm and a working feeding speed is 50 to 150 mm/second.

### BACKGROUND OF THE INVENTION

1. Field of the Invention

This invention relates to a working method for a sapphire substrate for dividing a sapphire substrate, which is used as a substrate of an optical device wafer or the like, along a planned dividing line set in advance.

2. Description of the Related Art

In an optical device manufacturing process, an optical device layer made of a gallium nitride-based compound semiconductor is layered on the surface of a sapphire substrate of a substantially disk shape, and a plurality of optical devices such as light emitting diodes or laser diodes are formed in different regions partitioned by a plurality of planned dividing lines formed in a lattice pattern. Then, the optical device wafer is divided along the planned dividing lines to manufacture the individual optical devices.

As a dividing method for dividing an optical device wafer along planned dividing lines described above, a method has been proposed wherein a pulse laser beam of a wavelength which is absorbable by a sapphire substrate which configures the optical device wafer is irradiated along a planned dividing line to carry out abrasion working to form a laser worked groove which serves as a start point of break and then applying external force along the planned dividing line along which the laser worked groove serving as a start point of break to divide the optical device wafer (refer to, for example, Japanese Patent Laid-Open No. Hei 10-305420). However, if a laser beam of a wavelength which is absorbable by a sapphire substrate is irradiated along a planned dividing line formed on the surface of an optical sapphire substrate which configures an optical device wafer to form a laser worked groove, then there is a problem that degenerated substance produced upon laser working sticks to a side wall face of an optical device such as a light emitting diode and drops the luminance of the optical device, resulting in degradation of the quality of the optical device.

Further, the division of the optical device wafer along a planned division line described above is carried out by a cutting apparatus called dicer. This cutting apparatus includes a chuck table for holding a work, cutting means for cutting the work held on the chuck table, and cutting feeding means for moving the chuck table and the cutting means relative to each other. The cutting means includes a rotary spindle, a cutting blade mounted on the spindle, and a driving mechanism for driving the rotary spindle to rotate. The cutting blade includes a disk-shaped base and an annular cutting edge mounted on a side face outer periphery of the base. The annular cutting edge is secured to the base by nickel plating of diamond grain of a particle size of, for example, 3 to 4 μm and is formed with a thickness of 20 to 30 μm (refer to, for example, Japanese Patent Laid-Open No. 2006-187834). By dividing an optical device wafer by such a cutting blade of a cutting apparatus as described above, an optical device can be worked without such production of degenerated substance on a side wall face thereof as in the case of laser working.

### SUMMARY OF THE INVENTION

However, since the sapphire substrate has a high Mohs hardness, in the case where a cutting groove is formed thereon by a cutting blade, the cutting is carried out at a working feeding speed of approximately 3 mm/second. However, there is a problem that the cutting blade is abraded severely and must be exchanged frequently, which is uneconomical and is poor in productivity.

Therefore, it is an object of the present invention to provide a working method for a sapphire substrate which can divide a sapphire substrate along a set planned dividing line while the abrasion amount of a cutting blade is reduced.

In accordance with an aspect of the present invention, there is provided a working method for a sapphire substrate for dividing a sapphire substrate along planned dividing lines, including a cutting groove forming step of positioning a cutting blade, which includes a cutting edge to which diamond grain is secured by metal plating, to a planned dividing line of the sapphire substrate and feeding the cutting blade and the sapphire substrate relative to each other for working while rotating the cutting blade to form a cutting groove, which serves as a start point of break, along the planned division line on the sapphire substrate, and a breaking step of applying external force to the sapphire substrate, for which the cutting groove forming step is carried out, to break the sapphire substrate along the planned dividing line along which the cutting groove is formed, the cutting groove forming step being set such that a rotational speed of the cutting blade is 20000 to 35000 rpm, a cutting-in depth of the cutting blade is 5 to 15 μm and a working feeding speed is 50 to 150 mm/second.

Preferably, the cutting groove forming step is carried out by a plural number of times along the planned dividing line to accumulate the depth of the cutting groove.

In the working method for a sapphire substrate according to the present invention, the cutting groove forming step of a cutting groove, which serves as a start point of break, along a planned division line on a sapphire substrate is set such that the rotational speed of the cutting blade is 20000 to 35000 rpm, the cutting-in depth of the cutting blade is 5 to 15 μm and the working feeding speed is 50 to 150 mm/second. Therefore, the cutting edge which configures the cutting blade is not damaged, and the abrasion amount of the cutting blade decreases and the productivity can be improved without causing any break with the sapphire substrate. Particularly, in the working method for a sapphire substrate according to the present invention, since the working feeding speed is set to 50 to 150 mm/second, working can be carried out at a working speed as high as 15 to 50 times the working feeding speed (3 mm/second) which has conventionally been regarded as a common sense in cutting working of a sapphire substrate, and the productivity can be improved. Further, the abrasion amount of the cutting blade decreases to equal to or less than ½, and the exchanging frequency of the cutting blade can be reduced to equal to or less than ½.

The above and other objects, features and advantages of the present invention and the manner of realizing them will become more apparent, and the invention itself will be best be understood, from a study of the following description and the appended claims with reference to the attached drawings showing some preferred embodiments of the invention.

### BRIEF DESCRIPTION OF THE DRAWINGS

FIG. 1A is a perspective view showing an optical device wafer which is worked in accordance with a working method for a sapphire substrate according to the present invention;

FIG. 1B is an enlarged sectional view of part of the optical device wafer;

FIGS. 2A and 2B are views illustrating a wafer supporting step in the working method for a sapphire substrate according to the present invention;

FIG. 3 is a partial perspective view of a cutting apparatus for carrying out a cutting groove forming step in the working method for a sapphire substrate according to the present invention;

FIG. 4 is a sectional view of a cutting blade equipped on the cutting apparatus shown in FIG. 3;

FIGS. 5A and 5B are views illustrating a cutting groove forming step in the working method for a sapphire substrate according to the present invention;

FIGS. 6A and 6B are sectional views showing, in an enlarged scale, part of an optical device wafer, for which the cutting groove forming step in the working method for a sapphire substrate according to the present invention is carried out;

FIGS. 7A and 7B are sectional views showing, in an enlarged scale, part of an optical device wafer for which the cutting groove forming step in the working method for a sapphire substrate according to the present invention is carried out by a plural number of times along a planned dividing line;

FIG. 8 is a perspective view of a wafer breaking apparatus for carrying out a breaking step in the working method for a sapphire substrate according to the present invention; and

FIGS. 9A and 9B are views illustrating the breaking step in the working method for a sapphire substrate according to the present invention.

### DETAILED DESCRIPTION OF THE PREFERRED EMBODIMENTS

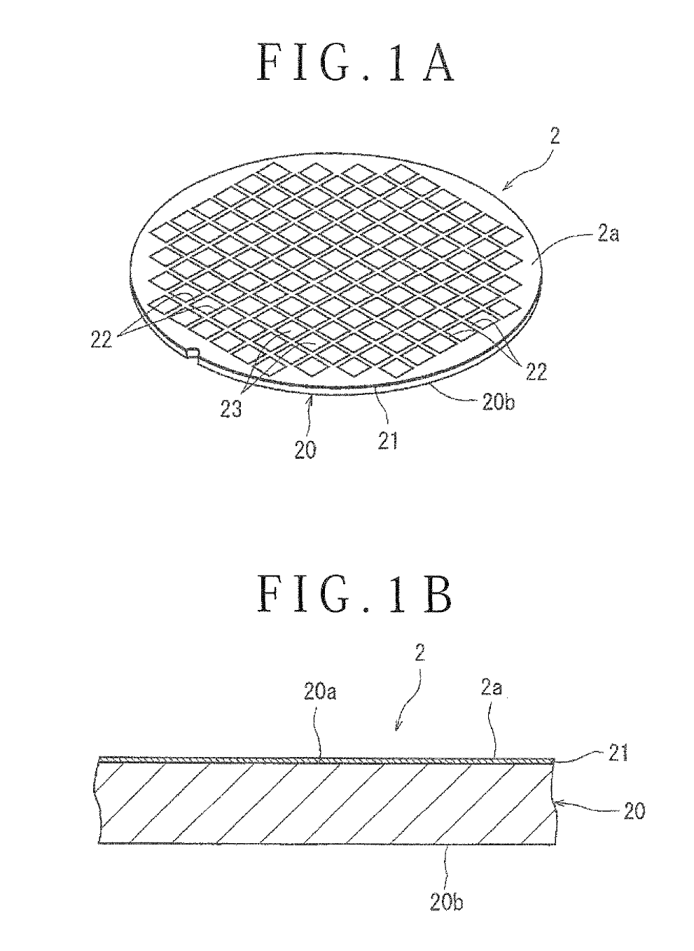

In the following, preferred embodiments of a working method for a sapphire substrate according to the present invention are described in detail with reference to the accompanying drawings. FIGS. 1A and 1B show a perspective view of an optical device wafer which is worked in accordance with a working method for a sapphire substrate according to the present invention and a sectional view showing, in an enlarged scale, of part of the optical device wafer, respectively. In the optical device wafer 2 shown in FIGS. 1A and 1B, a light emitting layer (epitaxial layer) 21 as an optical device layer made of nitride semiconductor is laminated with a thickness of 5 μm on a front face 20a of a sapphire substrate 20 having a thickness of, for example, 100 μm. Further, an optical device 23 such as a light emitting diode or a laser diode is formed in each of a plurality of regions of the light emitting layer (epitaxial layer) 21 partitioned by a plurality of planned dividing lines 22 formed in a lattice pattern. In the following, a working method for dividing the optical device wafer 2 into the individual optical devices 23 along the planned dividing lines 22 is described.

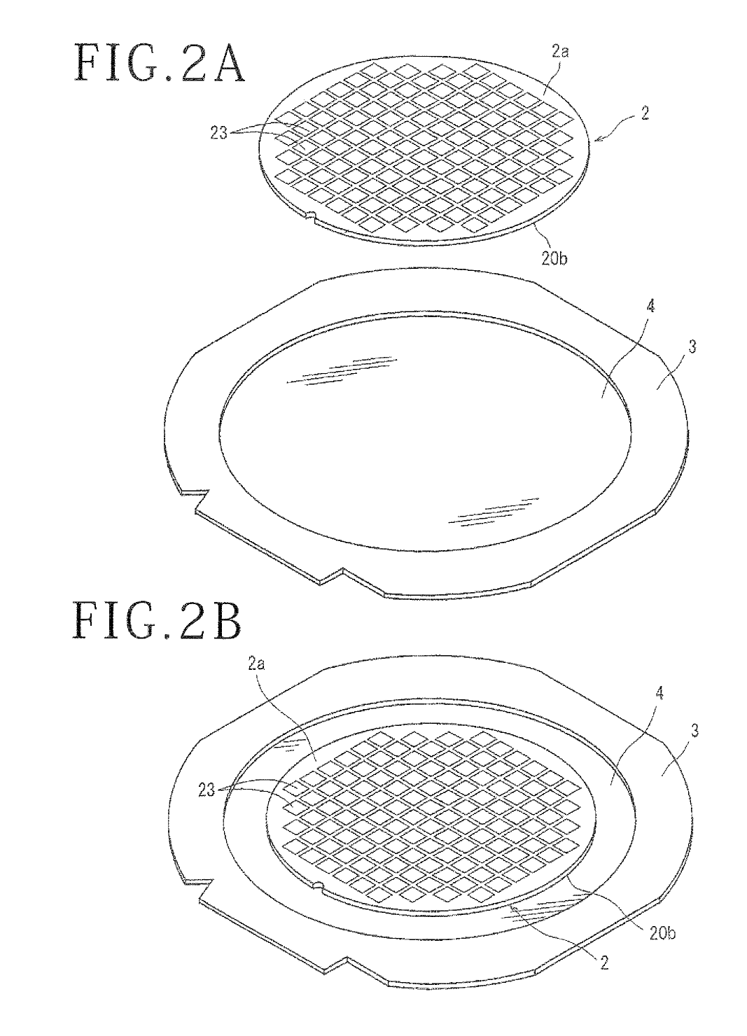

In the working method for a sapphire substrate according to the present invention, the sapphire substrate 20 which configures the optical device wafer 2 is first adhered at a rear face 20b thereof to the front face of a dicing tape 4 mounted on an annular frame 3 as shown in FIGS. 2A and 2B (wafer supporting step). After the wafer supporting step described above is carried out, a cutting groove forming step of positioning a cutting blade, which has a cutting edge to which diamond grain is secured by nickel plating, on a planned dividing line of the optical device wafer 2 formed from a sapphire substrate and feeding for working, while the cutting blade is rotated, the cutting blade and the sapphire substrate for working relative to each other to form a cutting groove which is used as a start point of break along the planned dividing line on the sapphire substrate is carried out.

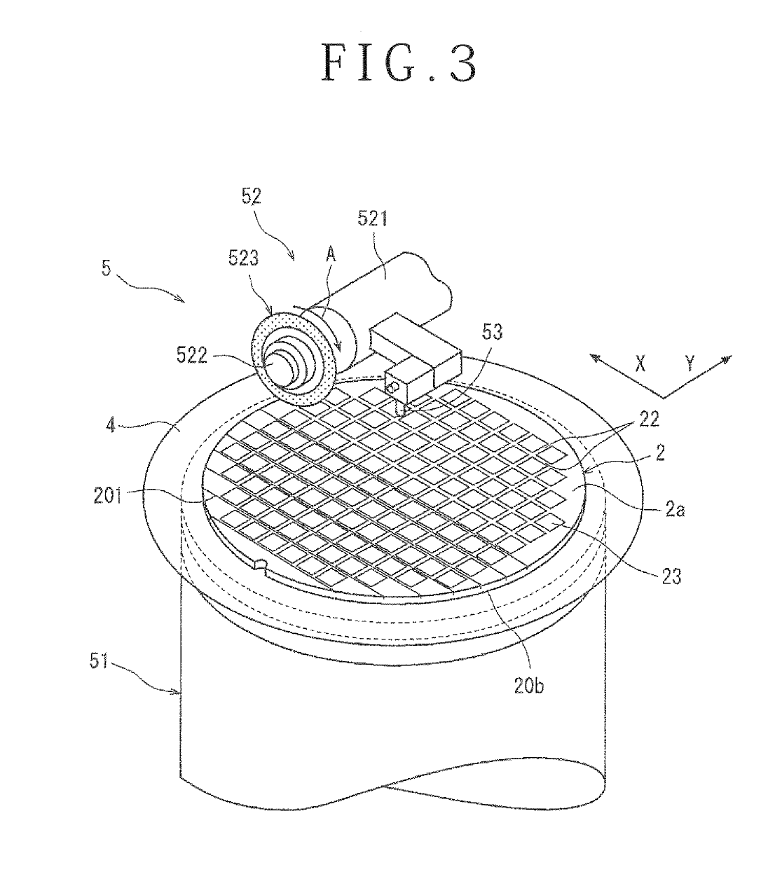

This cutting groove forming step is carried out, in the embodiment shown, using a cutting apparatus 5 shown in FIG. 3. The cutting apparatus 5 shown in FIG. 3 includes a chuck table 51 for holding a work, cutting means 52 for cutting the work held on the chuck table 51, and image pickup means 53 for picking up an image of the work held on the chuck table 51. The chuck table 51 is configured so as to suck and hold the work thereto and is moved in a working feeding direction indicated by an arrow mark X in FIG. 3 by cutting feeding means not shown and moved in an indexing feeding direction indicated by an arrow mark Y by indexing feeding means not shown.

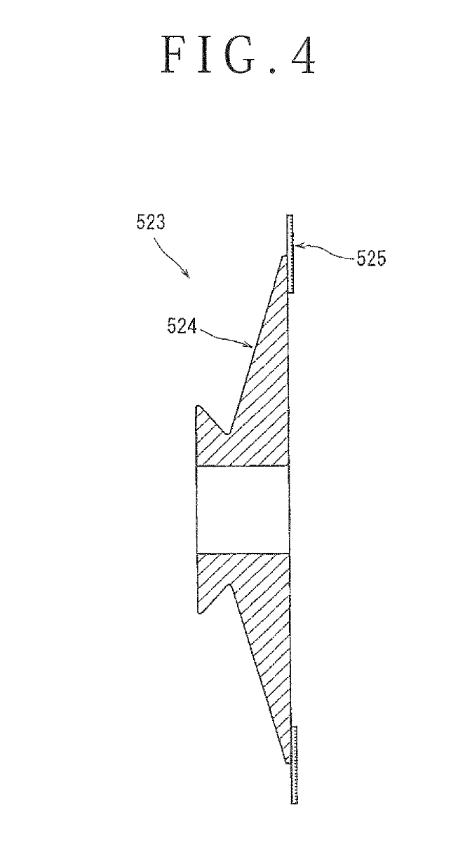

The cutting means 52 includes a spindle housing 521 disposed substantially horizontally, a rotary spindle 522 supported for rotation on the spindle housing 521, and a cutting blade 523 mounted at a tip end portion of the rotary spindle 522. The rotary spindle 522 is rotated in a direction indicated by an arrow mark A by a servo motor not shown disposed in the spindle housing 521. It is to be noted that the spindle housing 521 includes, as shown in FIG. 4, a base 524, and an annular cutting edge 525 mounted on a side face outer peripheral portion of the base 524. The annular cutting edge 525 is formed from an electroformed blade formed by securing diamond grain of a particle size of 3 to 4 μm to a side face outer peripheral portion of the base 524 by nickel plating, and is formed such that it has a thickness of 20 to 30 μm and an outer diameter of 52 mm. The image pickup means 53 is mounted at a tip end portion of the spindle housing 521, and includes illumination means for illuminating the work, an optical system for capturing a region illuminated by the illumination means, an image pickup element (CCD) for picking up an image captured by the optical system, and so forth. The image pickup means 53 sends a picked up image signal to control means not shown.

In order to carry out the cutting groove forming step using the cutting apparatus 5 described above, the sapphire substrate 20 which configures the optical device wafer 2 is placed at the dicing tape 4 side thereof, to which it is adhered at the rear face 20b thereof, on the chuck table 51 as shown in FIG. 3, and suction means not shown is rendered operative to suck and hold the optical device wafer 2 to the chuck table 51 with the dicing tape 4 interposed therebetween (wafer holding step). Accordingly, a front face 2a of the optical device wafer 2 held on the chuck table 51 is directed upwardly. It is to be noted that, while, in FIG. 3, the annular frame 3 on which the dicing tape 4 is mounted is omitted, the annular frame 3 is secured by a clamp mechanism disposed on the chuck table 51. In this manner, the chuck table 51 on which the optical device wafer 2 is sucked and held is positioned immediately below the image pickup means 53 by cutting feeding means not shown.

After the chuck table 51 is positioned immediately below the image pickup means 53, an alignment operation of detecting a region of the optical device wafer 2 to be worked is executed by the image pickup means 53 and the control means not shown. In particular, the image pickup means 53 and the control means not shown execute alignment for carrying out positioning between a planned dividing line 22 formed in a first direction on the front face 2a of the optical device wafer 2 and the cutting blade 523 (alignment step). Further, also for a planned dividing line 22 formed in a direction perpendicular to the first direction on the surface 2a of the optical device wafer 2, alignment of a working region is executed similarly.

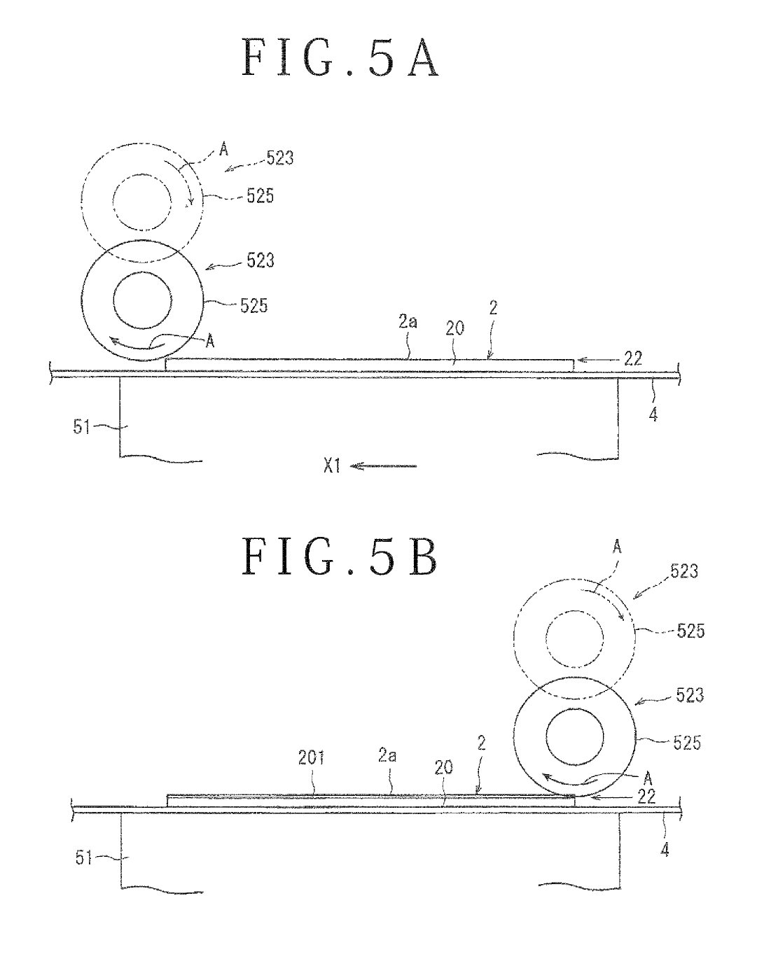

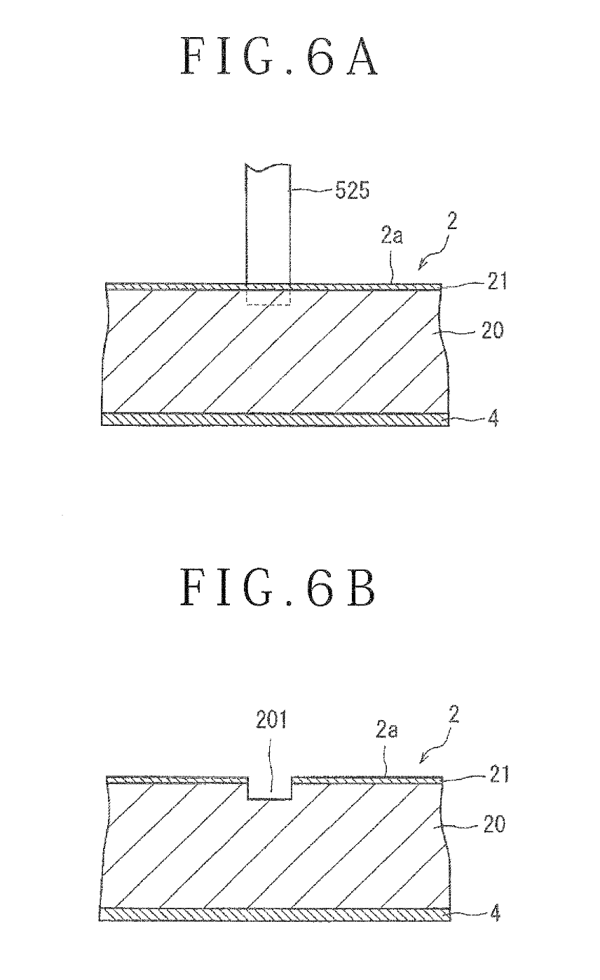

After the alignment for detecting the working region of the optical device wafer 2 held on the chuck table 51 is carried out in such a manner as described above, the chuck table 51 on which the optical device wafer 2 is sucked and held is moved to a working starting position of the working region below the cutting blade 523. Then, the optical device wafer 2 is positioned such that one end (left end in FIG. 5A) of the planned dividing line 22 thereof to be worked is positioned on the right side by a predetermined amount with respect to the position immediately below the cutting blade 523 (working feeding starting position positioning step). After the optical device wafer 2 is positioned at the working starting position of the working region in this manner, the cutting blade 523 is fed for cutting-in downwardly from a waiting position indicated by an alternate long and two short dashes line in FIG. 5A while it is rotated in the direction indicated by an arrow mark A until it is positioned at a predetermined cutting-in feeding position as indicated by a solid line in FIG. 5A. This cutting-in feeding position is set to a position at which a lower end of the outer peripheral edge of the annular cutting edge 525 which configures the cutting blade 523 is positioned downwardly, for example, by 5 to 15 μm from the front face 2a (upper face) of the optical device wafer 2 as shown in FIGS. 5A and 6A. It is to be noted that, if the cutting-in depth is set deeper than 15 μm, then the load applied to the cutting blade increases and some break or crack appears with the upper face of the sapphire substrate, and therefore, the cutting-in depth is limited to 15 μm. On the other hand, if the cutting-in depth is smaller than 5 μm, then although the load applied to the cutting blade is moderated, in order to form a cutting groove of the predetermined depth, it is necessary to carry out cutting by a plural number of times and the productivity is low. Accordingly, it is preferable to set the cutting-in depth of the cutting blade to 5 to 15 μm.

Then, while the cutting blade 523 is rotated at the predetermined rotational speed in the direction indicated by the arrow mark A as shown in FIG. 5A, the chuck table 51 is fed for working at a predetermined working feeding speed in a direction indicated by an arrow mark X1 in FIG. 5A (cutting groove forming step). As a result, on the optical device wafer 2, a cutting groove 201 of a depth of 5 to 15 μm which serves as a start point of break is formed along the planned dividing line 22. At this cutting groove forming step, preferably the rotational speed of the cutting blade 523 is set to 20000 to 35000 rpm and the working feeding speed is set to 50 to 150 mm/second. If the rotational speed of the cutting blade 523 is lower than 20000 rpm, then damage is likely to occur with the cutting blade, but if the rotational speed of the cutting blade exceeds 35000 rpm, then deflection occurs with the cutting blade and damages the sapphire substrate. Meanwhile, as regards the working feeding speed, according to an experiment of the inventor of the present invention, it has been found that, in the case where a cutting groove of a predetermined length is to be formed, as the working feeding speed decreases, the abrasion amount of the annular cutting edge which configures the cutting blade increases, and as the working feeding speed increases, the abrasion amount of the annular cutting edge which configures the cutting blade decreases. In the following, an example of the experiment of the inventor is described.

### Experiment Example

A sapphire substrate was cut using a cutting blade including a cutting edge formed from an electroformed blade formed by securing diamond grain of a particle size of 3 to 4 μm by nickel plating and having a thickness of 30 μm and an outer diameter of 52 mm. The working conditions at this time were that the cutting-in depth was 15 μm; the rotational speed of the cutting blade was 30000 rpm; the working feeding speed was set stepwise within the range of 1 to 150 mm/second; and the cutting working was carried out for 1 m. The following results were obtained by the experiment.

(1) In the case where the working feeding speed was 1 mm/second, the abrasion amount of the cutting edge which configured the cutting blade was 7 μm/working length 1 m.

(2) In the case where the working feeding speed was 3 mm/second, the abrasion amount of the cutting edge which configured the cutting blade was 6 μm/working length 1 m.

(3) In the case where the working feeding speed was 10 mm/second, the abrasion amount of the cutting edge which configured the cutting blade was 5 μm/working length 1 m.

(4) In the case where the working feeding speed was 30 mm/second, the abrasion amount of the cutting edge which configured the cutting blade was 4 μm/working length 1 m.

(5) In the case where the working feeding speed was 50 mm/second, the abrasion amount of the cutting edge which configured the cutting blade was 2.5 μm/working length 1 m.

(6) In the case where the working feeding speed was 100 mm/second, the abrasion amount of the cutting edge which configured the cutting blade was 2 μm/working length 1 m.

(7) In the case where the working feeding speed was 150 mm/second, the abrasion amount of the cutting edge which configured the cutting blade was 1.8 μm/working length 1 m.

(8) In the case where the working feeding speed was 160 mm/second, the abrasion amount of the cutting edge which configured the cutting blade was 1.8 μm/working length 1 m. However, some break appeared with the sapphire substrate.

From the experiment results described above, it is recognized that, as the working feeding speed decreases, the abrasion amount of the cutting edge which configures the cutting blade increases, and as the working feeding speed increases, the abrasion amount of the cutting edge which configures the cutting blade decreases. Particularly if the working feeding speed is set to 50 mm/second, then the abrasion amount of the cutting edge which configures the cutting blade is 2.5 μm/working length 1 m, and in comparison with that in a case of a working feeding speed (3 mm/second) which has conventionally been regarded as a common sense in cutting working of a sapphire substrate, the abrasion amount decreases to 42%, and the lifetime of the cutting blade improves by twice or more. Further, if the working feeding speed is set to 150 mm/second, then the abrasion amount of the cutting edge which configures the cutting blade is 1.8 μm/working length 1 m, and in comparison with that in a case of a working feeding speed (3 mm/second) which has conventionally been regarded as a common sense in cutting working of a sapphire substrate, the abrasion amount decreases to 30% and the lifetime of the cutting blade becomes three times or more. On the other hand, if the working feeding speed is 160 mm/second exceeding 150 mm/second, then since some break appears with the sapphire substrate, and therefore, preferably the working feeding speed is set not higher than 150 mm/second.

In this manner, by setting the working feeding speed to 50 to 150 mm/second, in comparison with that in a case of a working feeding speed (3 mm/second) which has conventionally been regarded as a common sense in cutting working of a sapphire substrate, the abrasion amount of the cutting edge which configures the cutting blade becomes equal to or lower than ½, and therefore, the exchanging frequency of the cutting blade can be reduced to equal to or less than ½, which is economical. Further, by setting the working feeding speed to 50 to 150 mm/second, working can be carried out at a working speed as high as 15 to 50 times the working feeding speed (3 mm/second) which has conventionally been regarded as a common sense in cutting working of a sapphire substrate without causing any break with the sapphire substrate or without damage to the cutting edge which configures the cutting blade, and the productivity can be improved.

After the cutting groove forming step is carried out along all of the planned dividing lines 22 extending in the first direction of the optical device wafer 2 in such a manner as described above, the chuck table 51 is turned by 90 degrees and the cutting groove forming step described above is carried out along the planned dividing lines 22 formed in the direction perpendicular to the first direction described above.

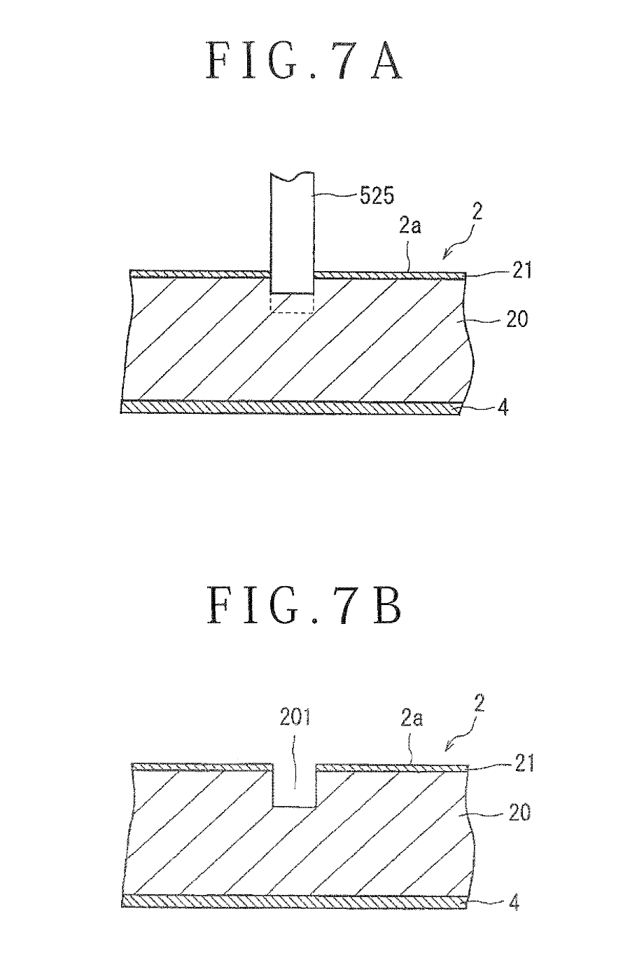

It is to be noted that, in the case where a sapphire substrate is cut in such a manner as described above, if the cutting-in depth is increased from 15 μm, then a load is applied to the cutting blade and some break or crack appears with an upper face of the sapphire substrate, and therefore, the cutting-in depth of the cutting blade is limited to 15 μm. Accordingly, in the case where it is intended to set the depth of a cutting groove, which serves as a start point of break, for example, to 30 μm, then the cutting groove forming step is carried out again in the region in which the cutting groove 201 is formed for the optical device wafer 2 on which the cutting groove 201 which serves as a start point of break is formed along the planned dividing line 22 as described above. In particular, the cutting edge 525 which configures the cutting blade 523 is positioned in the region in which the cutting groove 201 is formed as shown in FIG. 7A, and the cutting blade 523 is fed for cutting such that a lower end of an outer circumferential edge of the cutting edge 525 which configures the cutting blade 523 comes to a position lower by 30 μm from the front face 2a (upper face) of the optical device wafer 2 (to a position lower by 15 μm than the bottom face of the cutting groove 201) to carry out the cutting groove forming step described hereinabove. As a result, a cutting groove 201 of 30 μm from the front face 2a (upper face) is formed on the optical device wafer 2 as shown in FIG. 7B.

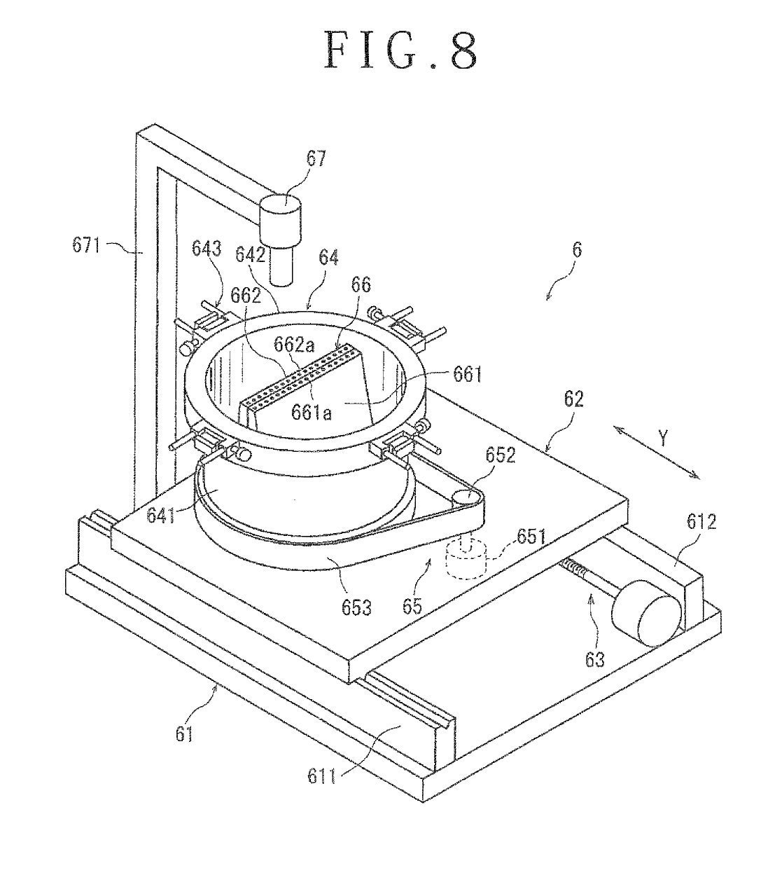

If the cutting groove forming step is carried out in such a manner as described above, then external force is applied to the optical device wafer to carry out a breaking step of breaking the optical device wafer along the planned dividing line along which a cutting groove 201 which serves as a start point of break is formed. This breaking step is carried out using a wafer breaking apparatus 6 shown in FIG. 8. The wafer breaking apparatus 6 shown in FIG. 8 includes a base 61, and a movable table 62 disposed for movement in directions indicated by a double-sided arrow mark Y on the base 61. The base 61 is formed in a rectangular shape, and two guide rails 611 and 612 are formed in parallel to each other in the directions indicated by the arrow mark Y on an upper face of the opposite side portions of the base 61. The movable table 62 is disposed for movement on the two guide rails 611 and 612. The movable table 62 is moved in the directions indicated by the arrow mark Y by moving means 63. On the movable table 62, frame holding means 64 for holding the annular frame 3 described hereinabove is disposed. The frame holding means 64 includes a cylindrical main body 641, an annular frame holding member 642 provided at an upper end of the main body 641, and a plurality of clamps 643 disposed on an outer periphery of the frame holding member 642 and serving as fixing means. The frame holding means 64 configured in such a manner as described above secures the annular frame 3 placed on the frame holding member 642 by means of the clamps 643. Further, the wafer breaking apparatus 6 shown in FIG. 8 includes rotating means 65 for rotating the frame holding means 64. The rotating means 65 includes a stepping motor 651 disposed on the movable table 62, a pulley 652 mounted on a rotary shaft of the stepping motor 651, and an endless belt 653 extending between and around the pulley 652 and the cylindrical main body 641. In the rotating means 65 configured in this manner, the stepping motor 651 is driven to rotate the frame holding means 64 through the pulley 652 and the endless belt 653.

The wafer breaking apparatus 6 shown in FIG. 8 includes tensile force application means 66 for causing tensile force to act upon the optical device wafer 2 supported through the dicing tape 4 on the annular frame 3 held on the annular frame holding means 64 in a direction perpendicular to a planned dividing line 22. The tensile force application means 66 is disposed in the annular frame holding means 64. This tensile force application means 66 includes a first sucking holding member 661 and a second sucking holding member 662 each provided with a holding face of a rectangular shape elongated in a direction perpendicular to the direction of the arrow mark Y. A plurality of suction holes 661a are formed in the first sucking holding member 661, and a plurality of suction holes 662a are formed in the second sucking holding member 662. The plural suction holes 661a and 662a are communicated with suction means not shown. Further, the first sucking holding member 661 and the second sucking holding member 662 are individually moved in the directions of the arrow mark Y by moving means not shown.

The wafer breaking apparatus 6 shown in FIG. 8 includes detection means 67 for detecting a planned dividing line 22 of an optical device wafer 2 supported through the dicing tape 4 on the annular frame 3 held on the annular frame holding member 642. The detection means 67 is attached to an L-shaped support post 671 disposed on the base 61. This detection means 67 is configured from an optical system, an image pickup device (CCD) and so forth and is disposed at a position above the tensile force application means 66. The detection means 67 configured in this manner picks up an image of a planned dividing line 22 of an optical device wafer 2 supported through the dicing tape 4 on the annular frame 3 held on the annular frame holding member 642 described hereinabove, converts the picked up image into an electric signal and sends the electric signal to the control means not shown.

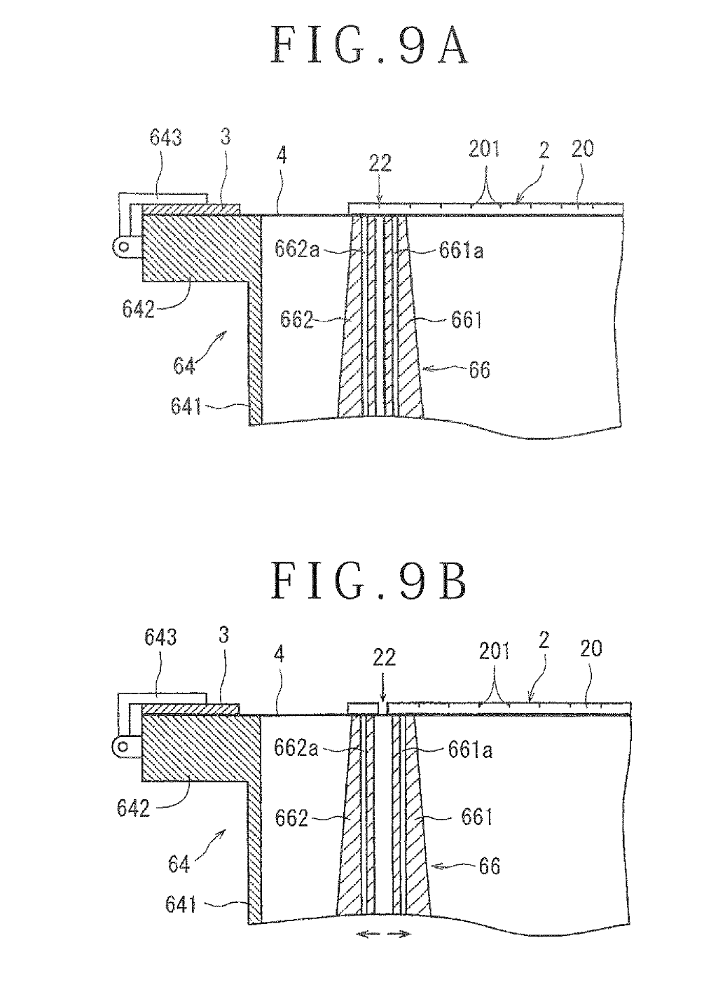

A wafer dividing step carried out using the wafer breaking apparatus 6 described hereinabove is described with reference to FIGS. 9A and 9B. The annular frame 3 for supporting an optical device wafer 2, for which the cutting groove forming step described hereinabove is to be carried out, thereon through the dicing tape 4 is placed on the frame holding member 642 as shown in FIG. 9A, and is secured to the frame holding member 642 by the clamps 643. Then, the moving means 63 is rendered operative to move the movable table 62 in a direction indicated by the arrow mark Y (refer to FIG. 8) until one of the planned dividing lines 22 (in the embodiment shown, the planned driving line at the left end) formed in a predetermined direction on the optical device wafer 2 as shown in FIG. 9A is positioned between a holding face of the first sucking holding member 661 and a holding face of the second sucking holding member 662 which configure the tensile force application means 66. At this time, an image of the planned dividing line 22 is picked up by the detection means 67 to carry out positioning of the holding face of the first sucking holding member 661 and the holding face of the second sucking holding member 662. If the one planned dividing line 22 is positioned between the holding face of the first sucking holding member 661 and the holding face of the second sucking holding member 662 in this manner, then the suction means not shown is rendered operative so that a negative pressure acts upon the suction holes 661a and 662a thereby to suck and hold the optical device wafer 2 to the holding face of the first sucking holding member 661 and the holding face of the second sucking holding member 662 through the dicing tape 4 (holding step).

If the holding step described above is carried out, then the moving means not shown which configures the tensile force application means 66 is rendered operative to move the first sucking holding member 661 and the second sucking holding member 662 in directions in which they are spaced away from each other as shown in FIG. 9B. As a result, tensile force in a direction perpendicular to the planned dividing line 22 acts upon the planned dividing line 22 positioned between the holding face of the first sucking holding member 661 and the holding face of the second sucking holding member 662, and the cutting groove 201 serves as a start point of break so that the optical device wafer 2 is broken along the planned dividing line 22 (breaking step). By carrying out this breaking step, the dicing tape 4 is extended a little. Since, at this breaking step, the cutting groove 201 is formed along the planned dividing line 22 and the strength of the optical device wafer 2 is lowered there, by moving the first sucking holding member 661 and the second sucking holding member 662 by approximately 0.5 mm in the directions in which they are spaced away from each other, the optical device wafer 2 can be broken along the planned dividing line 22 whereupon the cutting groove 201 formed on the sapphire substrate 20 serves as a start point of the break.

If the breaking step of breaking the optical device wafer 2 along one planned dividing line 22 formed in the first direction is carried out in such a manner as described above, then the suction holding of the optical device wafer 2 by the first sucking holding member 661 and the second sucking holding member 662 described above is canceled. Then, the moving means 63 is rendered operative to move the movable table 62 by a distance corresponding to the distance between the planned dividing lines 22 in the direction indicated by the arrow mark Y (refer to FIG. 8) so that a planned dividing line 22 neighboring with the planned dividing line 22, for which the breaking step has been carried out, is positioned between the holding face of the first sucking holding member 661 and the holding face of the second sucking holding member 662 which configure the tensile force application means 66. Then, the holding step and the breaking step described above are carried out.

If the holding step and the breaking step are carried out for all planned dividing lines 22 formed in the first direction in such a manner as described above, then the rotating means 65 is rendered operative to rotate the frame holding means 64 by 90 degrees. As a result, also the optical device wafer 2 held on the frame holding member 642 of the frame holding means 64 rotates by 90 degrees, and a planned dividing line 22 formed in the direction perpendicular to the planned dividing lines 22 which are formed in the first direction and for which the breaking step has been carried out is positioned in a state in which it extends in parallel to the holding face of the first sucking holding member 661 and the holding face of the second sucking holding member 662. Then, by carrying out the holding step and the breaking step described hereinabove for all planned dividing lines 22 formed in the direction perpendicular to the planned dividing lines 22 for which the breaking step has been carried out, the optical device wafer 2 is divided along the planned dividing lines 22 into the individual optical devices 23.

The present invention is not limited to the details of the above described preferred embodiments. The scope of the invention is defined by the appended claims and all changes and modification as fall within the equivalence of the scope of the claims are therefore to be embraced by the invention.

What is claimed is:

1. A working method for a sapphire substrate for dividing a sapphire substrate along planned dividing lines, comprising:
a cutting groove forming step of positioning a cutting blade, which includes a cutting edge to which diamond grain is secured by metal plating, to a planned dividing line of the sapphire substrate and feeding the cutting blade and the sapphire substrate relative to each other for working while rotating the cutting blade to form a cutting groove, which serves as a start point of break, along the planned division line on the sapphire substrate; and
a breaking step of applying external force to the sapphire substrate, for which the cutting groove forming step is carried out, to break the sapphire substrate along the planned dividing line along which the cutting groove is formed;
the cutting groove forming step being set such that a rotational speed of the cutting blade is 20000 to 35000 rpm, a cutting-in depth of the cutting blade is 5 to 15 μm and a working feeding speed is 50 to 150 mm/second.

2. The working method for a sapphire substrate according to claim 1, wherein the cutting groove forming step is carried out by a plural number of times along the planned dividing line to accumulate the depth of the cutting groove.
